(19) United States
(12) Patent Application Publication
(10) Pub. No.: US 2007/0278638 A1
(43) Pub. Date: Dec. 6, 2007

(54) Semiconductor package structure

(75) Inventors: Kuo-Liang Wu, Hsin-Tien City (TW); Kuo-Shu Lu, Hsin-Tien City (TW); Chih-Wei Chang, Hsin-Tien City (TW)

Correspondence Address: ROSENBERG, KLEIN & LEE, 3458 ELLICOTT CENTER DRIVE-SUITE 101, ELLICOTT CITY, MD, 21043, US

(73) Assignee: LITE-ON SEMICONDUCTOR CORPORATION

(21) Appl. No.: 11/445,169

(22) Filed: Jun. 2, 2006

(51) Int. Cl. H01L 23/02

(52) U.S. Cl. 257/686

(57) ABSTRACT

A semiconductor package structure includes a substrate, a chip module, a lead frame, and a bridging element. The chip module is electrically connected to the substrate. The lead frame is disposed beside one side of the substrate, wherein the lead frame has a receiving unit. The bridging element has one side electrically connected with the chip module, and the bridging element has a positioning unit is formed on the other side thereof for electrically retaining in the receiving unit. Moreover, the semiconductor package structure of the present invention is applied to the design of multi-chip package, and ensures that a bridging element is connected with a chip via the bridging element retained with a lead frame. In addition, the junction between the bridging element and the lead frame do not cause displacement between the lead frame and the bridging element during the packaging process.

### BACKGROUND OF THE INVENTION

1. Field of The Invention

The present invention relates to a semiconductor package structure, and particularly relates to a semiconductor package structure for increasing the retaining property between a bridging element and a lead frame.

2. Description of the Related Art

Presently, the size of semiconductor chips are becoming smaller and smaller. Consequently, the available interior space of a semiconductor chip is being reduced at a relative rate. Hence, not only is it difficult to design a lead frame for a semiconductor chip, but it is also becoming more difficult to design the chip's bridging element. In general, a bad bridging element will usually cause problems such as the making the semiconductor's electrical property becoming less efficient, making the semiconductor difficult to package, and causing the soldering to be bad. Hence, the above-mentioned problems cause the product yield rate to be reduced and increase costs.

Referring to FIG. 1, a known semiconductor package structure includes a substrate 1a, a chip 2a, a lead frame 3a, a bridging element 4a, and a support block 5a. The chip 2a is electrically disposed on the substrate 1a, and the lead frame 3a is disposed beside the substrate 1a. In addition, the support block 5a is electrically disposed on the chip 2a for making a top surface of the support block 5a and a top contact point 30a of the lead frame 3a in the same level. Hence, it is easy for the bridging element 4a to be electrically disposed between the support block 5a and the lead frame 3a. In other words, when the bridging element 4a is disposed between the support block 5a and the lead frame 3a, the bridging element 4a is in a parallel status.

However, the known bridging element 4a is difficult to position correctly as the bridging element 4a is easily separated from the lead frame 3a. As such, the quality of the known semiconductor package structure is unstable, and its electric and mechanical properties are not easily controlled. Hence, the yield rate of the known semiconductor package structure is difficult to increase.

### SUMMARY OF THE INVENTION

The present invention provides a semiconductor package structure applied to the design of multi-chip package. The semiconductor package structure of the present invention ensures that because the bridging element is retained by the lead frame the connection between the bridging element and the chip is correct. In addition, the junction between the bridging element and the lead frame does not cause any displacement between the lead frame and the bridging element during the packaging process.

Moreover, the present invention has other positive functions such as good positioning, enhancement of the mold locking between the bridging element and the lead frame via the package colloid, fixing the soldering position (the offset and defection of the bridging element are limited), prevention of solder opening and the joint drying (small holes in the lead frame absorb unnecessary solder, and air in the solder can be discharged during soldering). In addition, because the soldering is stable, the forward voltage drop is stable. Hence, the present invention not only reduces the power dissipation, but also increases product yield rate and quality.

One aspect of the present invention is a semiconductor package structure. The semiconductor package structure comprises a substrate, a chip module, a lead frame, and a bridging element. The chip module is electrically connected to the substrate. The lead frame is disposed beside one side of the substrate, wherein the lead frame has a receiving unit. The bridging element has one side electrically connected with the chip module, wherein the bridging element has a positioning unit formed on the other side thereof for electrically retaining in the receiving unit.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a cross-sectional view of a semiconductor package structure according to a prior art;

FIG. 2 is a perspective, exploded view of a semiconductor package structure according to a first embodiment of the present invention;

FIG. 3 is a perspective, assembled view of a semiconductor package structure according to a first embodiment of the present invention;

FIG. 4 is a cross-sectional view along line 4-4 of the semiconductor package structure shown in FIG. 3;

FIG. 5 is a perspective, exploded view of a semiconductor package structure according to a second embodiment of the present invention;

FIG. 6 is a perspective, assembled view of a semiconductor package structure according to a second embodiment of the present invention;

FIG. 7 is a cross-sectional view along line 7-7 of the semiconductor package structure shown in FIG. 6;

FIG. 8 is a perspective, exploded view of a semiconductor package structure according to a third embodiment of the present invention; and

FIG. 9 is a perspective, assembled view of a semiconductor package structure according to a third embodiment of the present invention.

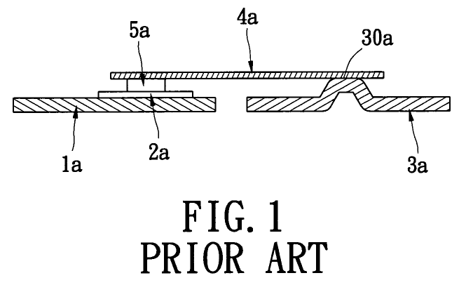

### DETAILED DESCRIPTION OF PREFERRED BEST MOLDS

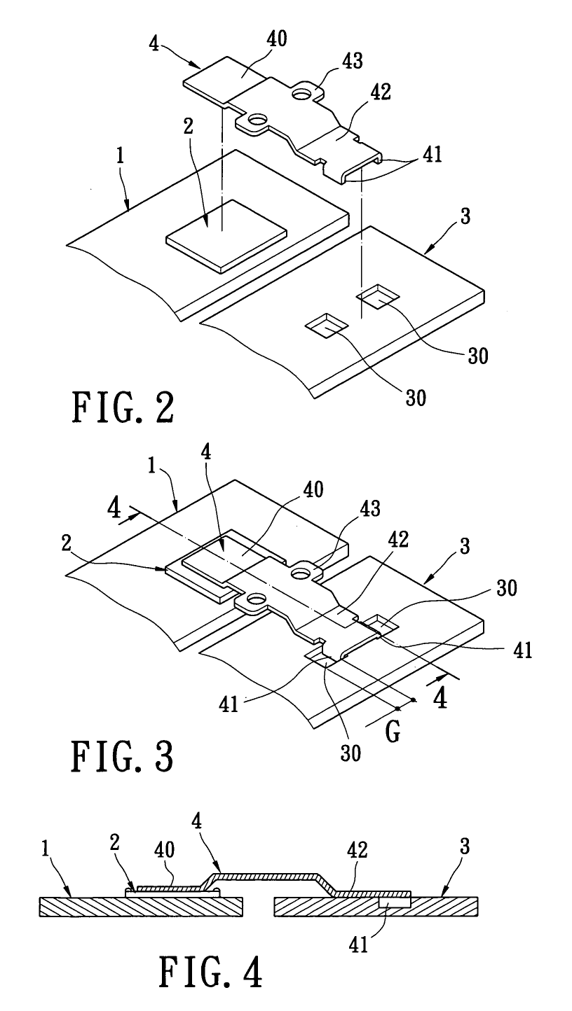

Referring to FIGS. 2-4, a first embodiment of the present invention provides a semiconductor package structure, comprising a substrate 1, a chip module 2, a lead frame 3, and a bridging element 4.

The chip module 2 is electrically connected to the substrate 1, and the chip module 2 can be a multi-chip module. Moreover, the lead frame 3 is disposed beside one side of the substrate 1. The lead frame 3 has a receiving unit, and the receiving unit includes two concave grooves 30. In addition, the bridging element 4 has a first extending portion 40 formed on one side thereof, and the bridging element 4 is electrically connected with the chip module 2 via the first extending portion 40. Furthermore, the bridging element 4 has a positioning unit formed on the other side thereof for electrically retaining in the receiving unit, and the positioning unit includes two positioning plugs 41 correspondingly received in the two concave grooves 30.

Moreover, a size of each positioning plug 41 is smaller than that of each concave groove 30, so that when the two positioning plugs 41 are received in the two concave grooves 30 respectively, and a gap G is produced between each positioning plug 41 and each concave groove 30. In addition, each concave groove 30 can be a circular or rectangular concave groove, and each positioning plug 41 can be a circular or rectangular positioning plug corresponding to the circular or rectangular concave groove. However, the above-mentioned shapes of the concave groove 30 or the positioning plug 41 should not be used to limit the present invention. In other words, both the concave groove 30 and the positioning plug 41 can be any corresponding shape.

Furthermore, the bridging element 4 has a second extending portion 42 formed on the other side thereof, and a connecting portion 43 connected between the first extending portion 40 and the second extending portion 42. In addition, the second extending portion 42 is connected with the positioning unit (the positioning plug 41) and is horizontally attached on the lead frame 3. The connecting portion 43 is higher than the first extending portion 40 and the second extending portion 42.

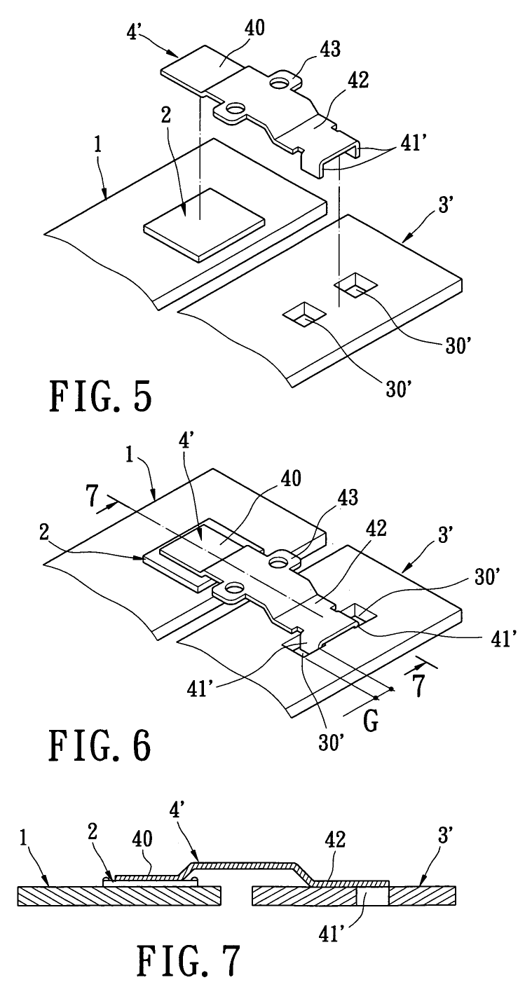

Referring to FIGS. 5-7, a second embodiment of the present invention provides a semiconductor package structure. The difference between the first embodiment and the second embodiment is that the second embodiment of the present invention comprises a lead frame 3′ with a receiving unit and a bridging element 4′ with a positioning unit.

Moreover, the receiving unit includes two through hole 30′, and the positioning unit includes two positioning plugs 41′ correspondingly passed through the two through holes 30′. In addition, each through hole 30′ can be a circular or rectangular through hole, and each positioning plug 41′ can be a circular or rectangular positioning plug corresponding to the circular or rectangular through hole. However, the above-mentioned shapes of the through hole 30′ or the positioning plug 41′ should not be used to limit the present invention. In other words, both the through hole 30′ and the positioning plug 41′ can be any corresponding shape.

Furthermore, each positioning plug 41′ has a size smaller than that of each through hole 30′, so that when the two positioning plugs 41′ are passed through the two through holes 30′ respectively, and a gap G is produced between each positioning plug 41′ and each through hole 30′.

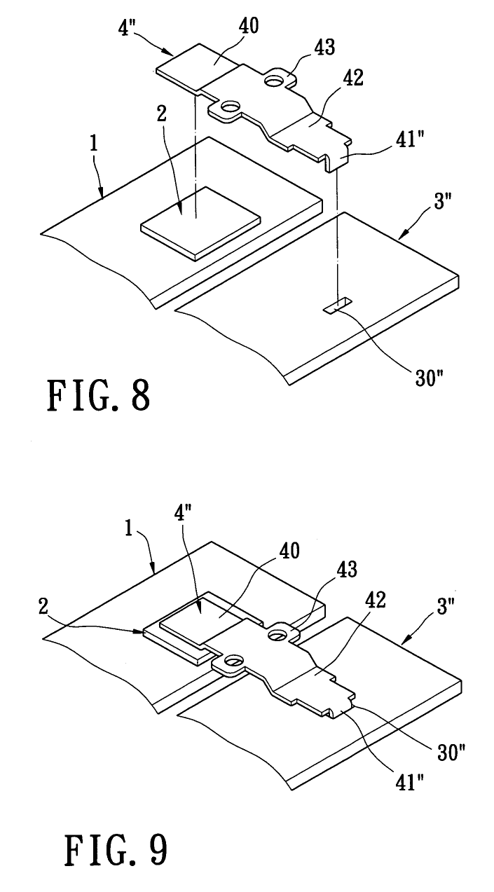

Referring to FIGS. 8 and 9, a third embodiment of the present invention provides a semiconductor package structure. The difference between the first and the second embodiment, and the third embodiment is that the third embodiment of the present invention comprises a lead frame 3″ with a receiving unit and a bridging element 4″ with a positioning unit.

Moreover, the receiving unit can be a concave groove 30″, and the positioning unit can be a positioning plug 41″ correspondingly received in the concave groove 30″. Alternatively, the receiving unit can be a through hole (not shown), and the positioning unit can be a positioning plug (not shown) correspondingly passed through the concave groove (not shown). In addition, as in the first and the second embodiment, the concave groove 30″ (or the through hole) can be a circular or rectangular concave groove (or through hole), and the positioning plug 41″ (or another positioning plug) can be a circular or rectangular positioning plug corresponding to the circular or rectangular concave groove (or through hole).

However, the quantity of the concave groove 30 and the positioning plug 41 should not be used to limit the present invention. In other words, all of the retaining methods between the concave groove 30 and the positioning plug 41 are within the scope of the present invention. In addition, the quantity of the through holes 30′ and the positioning plugs 41′ should not be used to limit the present invention. In other words, all of the penetrated retaining methods between the through hole 30′ and the positioning plug 41′ are within the scope of the present invention.

In conclusion, the semiconductor package structure of the present invention is applied to a design of multi-chip package. The semiconductor package structure of the present invention can ensure that a bridging element is connected with a chip via the bridging element retained by a lead frame. In addition, the junction between the bridging element and the lead frame does not cause displacement between the lead frame and the bridging element during the packaging process.

Moreover, the present invention has other positive functions such as good positioning, enhancement of the mold locking between the bridging element and the lead frame via the package colloid, fixing the soldering position (the offset and defection of the bridging element are limited), prevention of solder opening and the joint drying (small holes in the lead frame absorb unnecessary solder, and air in the solder can be discharged during soldering). In addition, because the soldering is stable, the forward voltage drop is stable. Hence, the present invention not only reduces power dissipation, but it also increases product yield rate and quality.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A semiconductor package structure, comprising:
a substrate;
a chip module electrically connected to the substrate;
a lead frame disposed beside one side of the substrate, wherein the lead frame has a receiving unit; and
a bridging element having one side electrically connected with the chip module, wherein the bridging element has a positioning unit formed on the other side thereof for electrically retaining in the receiving unit.

2. The semiconductor package structure as claimed in claim 1, wherein the chip module is a multi-chip module.

3. The semiconductor package structure as claimed in claim 1, wherein the receiving unit has at least one concave groove, and the positioning unit has at least one positioning plug correspondingly received in the at least one concave groove.

4. The semiconductor package structure as claimed in claim 3, wherein a size of the at least one positioning plug is smaller than that of the at least one concave groove, so that when the at least one positioning plug is received in the at least one concave groove, a gap is produced between the at least one positioning plug and the at least one concave groove.

5. The semiconductor package structure as claimed in claim 3, wherein the at least one concave groove is a circular or rectangular concave groove, and the at least one positioning plug is a circular or rectangular positioning plug corresponding to the circular or rectangular concave groove.

6. The semiconductor package structure as claimed in claim 1, wherein the receiving unit has at least one through hole, and the positioning unit has at least one positioning plug correspondingly passed through the at least one through hole.

7. The semiconductor package structure as claimed in claim 6, wherein a size of the at least one positioning plug is smaller than that of the at least one through hole, so that when the at least one positioning plug is received in the at least one through hole, a gap is produced between the at least one positioning plug and the at least one through hole.

8. The semiconductor package structure as claimed in claim 6, wherein the at least one through hole is a circular or rectangular through hole, and the at least one positioning plug is a circular or rectangular positioning plug corresponding to the circular or rectangular through hole.

9. The semiconductor package structure as claimed in claim 1, wherein the bridging element has a first extending portion formed on one side thereof, and the bridging element is electrically connected with the chip module via the first extending portion.

10. The semiconductor package structure as claimed in claim 9, wherein the bridging element has a second extending portion formed on the other side thereof, and a connecting portion connected between the first extending portion and the second extending portion, wherein the second extending portion is connected with the positioning unit and horizontally attached on the lead frame, and the connecting portion is higher than the first extending portion and the second extending portion.
